(19) United States
(12) Patent Application Publication
(10) Pub. No.: US 2024/0135060 A1
(43) Pub. Date: Apr. 25, 2024

(54) METHOD AND SYSTEM FOR DECOUPLING ELECTRIC FIELD OF ELECTROCHEMICAL MODEL BASED ON PARALLEL TARGETING METHOD

(71) Applicant: SHANGHAI MAKESENS ENERGY STORAGE TECHNOLOGY CO., LTD., Shanghai (CN)

(72) Inventors: Mingchen Jiang, Shanghai (CN); Danfei Gu, Shanghai (CN); Siyuan Chen, Shanghai (CN); Qian Li, Shanghai (CN); Liangchang Wei, Shanghai (CN); Xiao Yan, Shanghai (CN); Enhai Zhao, Shanghai (CN)

(21) Appl. No.: 18/379,334

(22) Filed: Oct. 12, 2023

(30) Foreign Application Priority Data
Oct. 13, 2022 (CN) 202211253056.9

(51) Int. Cl. G06F 30/20

(52) U.S. Cl. CPC G06F 30/20; H01M 10/0525

(57) ABSTRACT

The invention provides a method and system for decoupling electric field of electrochemical model based on a parallel targeting method. The method includes selecting a negative or positive electrode region as a calculation region; selecting a solid or liquid phase current as an observed quantity, and a solid and liquid phase potential as a costate variable; inserting nodes between two endpoints of the calculation region, and determining a target value of the observed quantity of each node; constructing N calculation units; respectively performing a target shooting on the N calculation units; and determining whether a distance between the target shooting value of the observed quantity of the end point of each calculation unit and the target value of the observed quantity of the node corresponding to the end point of the calculation unit is within a preset range.

### CROSS-REFERENCE TO RELATED PATENT APPLICATION

This application claims priority to and the benefit of Chinese Patent Application No. 202211253056.9, filed Oct. 13, 2022, which is incorporated herein in its entirety by reference.

### FIELD OF THE INVENTION

The invention relates to the field of batteries, and more particularly to a method and system for decoupling electric field of electrochemical model based on a parallel targeting method.

### BACKGROUND OF THE INVENTION

An electrochemical P2D (Pseudo-Two-Dimensional) model of the lithium ion battery can accurately simulate the electrochemical process of the lithium battery in the charging and discharging process, but the model is complex and suffers from issues such as high order, nonlinearity, parameter coupling, and the like.

In electric field coupling of the model, a series of partial differential equations of boundary value problems needs to be solved. The shooting method is a numerical method for solving boundary value problems, and the method has simple principles and high precision in calculation results. However, conventional shooting methods are highly dependent on the initial trial solution of the costate variable, and if the initial trial solution is not appropriate and the tracking length is long, it can easily lead to intermediate calculation data overflow in the tracking process and the shooting method failing to converge.

In order to solve the above problems, an improved method is to change one-time shooting into multiple serial shooting. The first target shooting has the smallest tracking length, so even if the initial trial solution of the first target shooting is not accurate, the small tracking length helps prevent data overflow during target shooting. In the next target shooting, the tracking length is increased, an initial trial solution of the next target shooting is determined according to the convergence solution obtained in the previous target shooting, and steps are repeated until the tracking length is increased to the maximum tracking length. The convergence solution refers to the trial solution of the costate variable at the target starting point that makes the observed quantity at the target end point converge to the target value of the observed quantity.

Because the initial trial solution used in subsequent target shooting is closer and closer to the true value, subsequent target shooting can still be ensured not to overflow even if the tracking length is increased.

It can be seen that the improved method requires multiple serial shooting, and compared to the conventional shooting method, although the problem of data overflow during target shooting is solved, the speed is much slower than that of the conventional shooting method.

### SUMMARY OF THE INVENTION

In view of the above-noted shortcomings, one of the objectives of this invention is to provide a method and a system for decoupling electric field of electrochemical model based on a parallel targeting method.

In one aspect of the invention, the method includes:
selecting a negative electrode region or a positive electrode region of the electrochemical model of a lithium ion battery as a calculation region;
selecting a solid phase current or a liquid phase current as an observed quantity, and a solid phase potential and a liquid phase potential as a costate variable;
inserting (N−1) nodes between two endpoints of the calculation region, and determining a target value of the observed quantity of each node according to a preset interpolation method;
constructing N calculation units, wherein the (N−1) nodes divide the calculation region into N sub-regions, each sub-region serving as a calculation unit;
respectively performing a target shooting on the N calculation units to obtain a target shooting value of the observed quantity of an end point of each calculation unit;
determining whether a distance between the target shooting value of the observed quantity of the end point of each calculation unit and the target value of the observed quantity of the node corresponding to the end point of said calculation unit is within a preset range; and
if the distance of any calculation unit is not within the preset range, adjusting the target value of the observed quantity of the node corresponding to the end point of said calculation unit according to the target shooting value of the observed quantity of the end point of said calculation unit, performing the target shooting on said N calculation units again, determining whether the distance between the target shooting value of the observed quantity of the end point of each calculation unit and the target value of the observed quantity of the corresponding node is within the preset range, and repeating above steps until said distances of all the calculation units are within the preset range.

In some embodiments, said determining the target value of the observed quantity of each node according to the preset interpolation method includes: according to the preset interpolation method, constructing an interpolation function, wherein values of the interpolation function at the two endpoints of the calculation region are respectively equal to values of the observed quantity of the endpoints corresponding to the calculation region, and wherein the preset interpolation method is one of a linear interpolation method, a Lagrange interpolation method and a Newton interpolation method; and calculating the target value of the observed quantity of each node according to the interpolation function.

In some embodiments, if the observed quantity is the solid phase current, obtaining the target value of the observed quantity at the i-th node by a formula of:

$$\frac{{i}_{external}}{L} \times ( L - {x}_{i} ) ,$$

wherein iₑₓₜₑᵣₙₐₗ is an external current, L is a thickness of an electrode, and xᵢ is a distance from the i-th node to a current collector.

In some embodiments, said adjusting the target value of the observed quantity of the node corresponding to the end point of said calculation unit according to the target shooting value of the observed quantity of the end point of said calculation unit includes:
constructing a target function according to the distance between the target shooting value of the observed quantity of the end point of all the calculation units and the target value of the observed quantity of the corresponding node;
obtaining an iterative update formula of the target value of the observed quantity of the node that enables the value of the target function to approach 0 by adopting an iterative method; and
adjusting the target value of the observed quantity of the node according to the iterative update formula.

In some embodiments, the iterative method is one of a Newton iterative method, a steepest descent method, a conjugate gradient method and a quasi-Newton iterative method.

In some embodiments, the (N−1) nodes are Chebyshev points.

In another aspect, the invention relates to a system for decoupling electric field of electrochemical model based on a parallel targeting method, wherein a negative electrode region or a positive electrode region of the electrochemical model of a lithium ion battery is selected as a calculation region, a solid phase current or a liquid phase current is selected as an observed quantity, and a solid phase potential and a liquid phase potential are selected as a costate variable, the system including:
an interpolation module, configured to insert (N−1) nodes between two endpoints of the calculation region, and determine a target value of the observed quantity of each node according to a preset interpolation method;
a unit construction module, configured to construct N calculation units, wherein the (N−1) nodes divide the calculation region into N sub-regions, each sub-region serving as a calculation unit;
a parallel target shooting module, configured to respectively perform a target shooting on the N calculation units to obtain a target shooting value of the observed quantity of an end point of each calculation unit;
a determination module, configured to determine whether a distance between the target shooting value of the observed quantity of the end point of each calculation unit and the target value of the observed quantity of the node corresponding to the end point of said calculation unit is within a preset range; and
an adjustment module, configured to, if the distance of any calculation unit is not within the preset range, adjust the target value of the observed quantity of the node corresponding to the end point of said calculation unit according to the target shooting value of the observed quantity of the end point of said calculation unit, perform the target shooting on said N calculation units again, determine whether the distance between the target shooting value of the observed quantity of the end point of each calculation unit and the target value of the observed quantity of the corresponding node is within the preset range, and repeat above steps until said distances of all the calculation units are within the preset range.

In some embodiments, said interpolation module is further configured to, according to the preset interpolation method, construct an interpolation function, wherein values of the interpolation function at the two endpoints of the calculation region are respectively equal to values of the observed quantity of the endpoints corresponding to the calculation region, and wherein the preset interpolation method is one of a linear interpolation method, a Lagrange interpolation method and a Newton interpolation method; and calculate the target value of the observed quantity of each node according to the interpolation function.

In some embodiments, said interpolation module is further configured to, if the observed quantity is the solid phase current, obtain the target value of the observed quantity at the i-th node by a formula of:

$$\frac{{i}_{external}}{L} \times ( L - {x}_{i} ) ,$$

wherein iₑₓₜₑᵣₙₐₗ is an external current, L is a thickness of an electrode, and xᵢ is a distance from the i-th node to a current collector.

In yet another aspect, the invention relates to a non-transitory tangible computer-readable storage medium, storing a computer program therein, wherein when the computer program is executed by a processor, the method for decoupling electric field of electrochemical model based on a parallel targeting method according to claim 1 is realized.

Compared with the prior art, the method and the system for decoupling electric field of electrochemical model based on a parallel targeting method can at least offer the following beneficial effects:

The invention divides the calculation region into N calculation units with small tracking length by inserting (N−1) nodes, first roughly setting the target value of the observed quantity of each node, then applying the targeting method in parallel for the N calculation units, and then iteratively adjusting the target value of the observed quantity of each node to ensure that the target shooting value of the observed quantity of the end point of each calculation unit converges to the target value of the observed quantity of the corresponding node, thereby obtaining a continuous and smooth targeting curve from the starting point to the end point of the calculation region, and obtaining electric field physical quantities such as current and potential of each spatial point in the calculation region according to the targeting curve. The invention not only avoids the phenomena that the conventional target shooting method has high dependency on the initial trial solution and data overflow or non-convergence easily occurs in the target shooting process, but also improves operational speed and processing efficiency compared with a multiple serial shooting method.

### BRIEF DESCRIPTION OF THE DRAWINGS

The accompanying drawings illustrate one or more embodiments of the invention and, together with the written description, serve to explain the principles of the invention. The same reference numbers may be used throughout the drawings to refer to the same or like elements in the embodiments.

FIG. 1 is a flowchart of a method for decoupling electric field of electrochemical model based on a parallel targeting method according to embodiments of the invention.

FIG. 2 is a schematic structural diagram of a system for decoupling electric field of electrochemical model based on a parallel targeting method according to embodiments of the invention.

FIG. 3 is a schematic structural diagram of a P2D model of a lithium ion battery.

FIG. 4 is a schematic diagram of a parallel targeting method according to embodiments of the invention.

FIG. 5 is a schematic diagram of Chebyshev points when M=8.

### DETAILED DESCRIPTION OF THE INVENTION

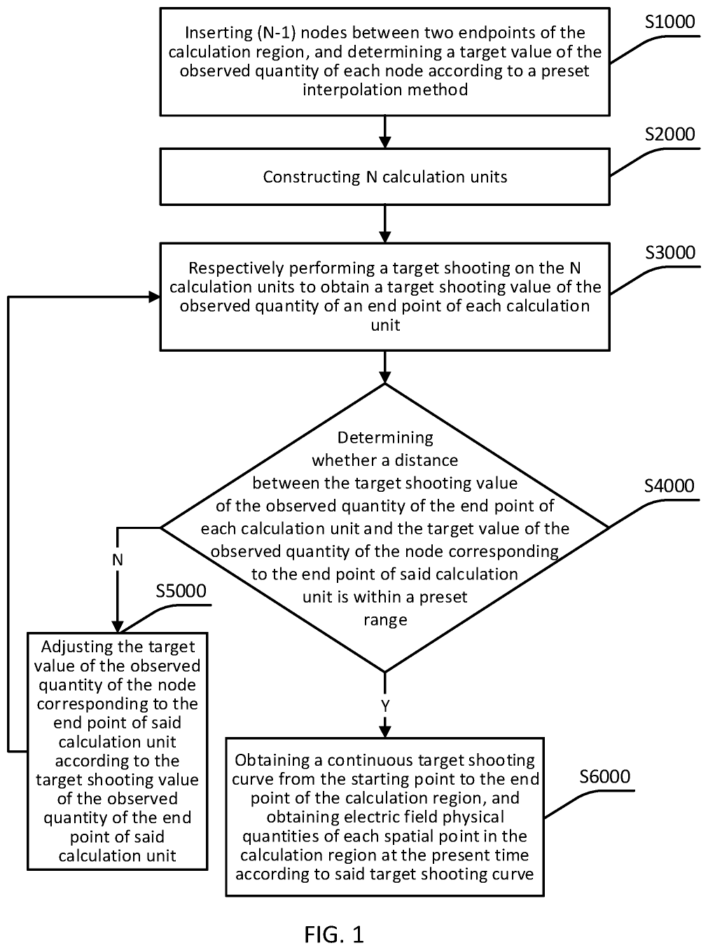

Embodiments of the invention are described below through specific examples in conjunction with the accompanying drawings in FIGS. 1-5, and those skilled in the art can easily understand other advantages and effects of the invention from the content disclosed in this specification. The invention can also be implemented or applied through other different specific implementations, and various modifications or changes can be made to the details in this specification according to different viewpoints and applications without departing from the spirit of the invention. It should be noted that, in the case of no conflict, the following embodiments and features in the embodiments can be combined with each other.

It should be noted that the drawings provided in the following embodiments are merely illustrative in nature and serve to explain the principles of the invention, and are in no way intended to limit the invention, its application, or uses. Only the components related to the invention are shown in the drawings rather than the number, shape and size of the components in actual implementations. For components with the same structure or function in some figures, only one of them is schematically shown, or only one of them is marked. They do not represent the actual structure of the product. Dimensional drawing, the type, quantity and proportion of each component can be changed arbitrarily in its actual implementations. More complicate component layouts may also become apparent in view of the drawings, the specification, and the following claims.

The terminology used herein is for the purpose of describing particular embodiments only and is not intended to be limiting of the invention. As used herein, “a” not only means “only one”, but also means “more than one”. The term “and/or” used in the description of the present application and the appended claims refers to any combination and all possible combinations of one or more of the associated listed items, and includes these combinations. The terms “first”, “second”, etc. are only used for distinguishing descriptions, and should not be construed as indicating or implying relative importance.

It should be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

In order to more clearly illustrate the embodiments of the invention or the technical solutions in the prior art, the following description will explain the specific embodiments of the invention with reference to the accompanying drawings. It is evident that the drawings in the following description are only examples of the invention, from which other drawings and other embodiments can be obtained by a person skilled in the art without inventive effort.

As described above, the conventional target shooting method is commonly used for electric field decoupling in the electrochemical model of the battery, that is, for solving electric field physical quantities such as current, potential, and the like at each spatial point in the electrochemical model. However, the conventional target shooting method has high dependency on the initial trial solution of costate variables. If the initial trial solution is not appropriate and the tracking length is long, it will lead to the overflow of intermediate calculation data, and the shooting will not converge. The multiple serial shooting method can solve these problems, but the processing speed is much slower than that of the conventional target shooting method due to the need for multiple sequential iterations, which limits its application in actual scenarios.

In view of the foregoing, the invention provides a parallel targeting method that uses a space-for-time method to improve the processing speed. First, a calculation region is divided into N calculation units with small tracking length by inserting (N−1) nodes, roughly setting a target value of the observed quantity of each node, then applying the targeting method in parallel for the N calculation units, obtaining a sub-curve from the targeting of each calculation unit. As the curve formed by the N sub-curves is discontinuous and unsmooth at first, the target value of the observed quantity of each node is then regulated through iteration, targeting the N calculation units again according to the new target value of the observed quantity of the node, and repeating the steps until the targeting of each unit converges and the curve formed by the N sub-curves becomes continuous and smooth. The observed value and the costate value of each node on the continuous and smooth curve are the required convergence solutions.

By targeting the N calculation units with small tracking lengths, data overflow during shooting can be prevented. Through the space-for-time method, the processing speed can be effectively improved.

The embodiments of the invention are described in detail below by taking a pseudo-two-dimensional (P2D) model of a lithium-ion battery as an example.

The schematic structure of the P2D model is shown in FIG. 3. The basic units of the lithium-ion battery are respectively a copper current collector 110, a negative electrode 120, a separator 130, a positive electrode 140, and an aluminum current collector 150. From the perspective of spatial distribution, a lithium-ion battery can be divided into three domains/regions, that is, a negative electrode region 120, a separator region 130, and a positive electrode region 140. The width of the positive electrode region is Lp, the width of the negative electrode region is Ln, and the width of the separator region is Ls.

In some embodiments, a planar coordinate system is established for the battery, and the x-axis is established along the direction from the negative electrode 120 to the positive electrode 140.

In one embodiment, as shown in FIG. 1, the method for decoupling electric field of electrochemical model based on a parallel targeting method is applied to a lithium ion battery, and includes the following steps:

In one embodiment, a negative electrode region or a positive electrode region of the electrochemical model of a lithium ion battery is selected as a calculation region. The calculation region has two endpoints, one of which is designated as a starting point and the other as an end point.

In one embodiment, a solid phase current or a liquid phase current is selected as an observed quantity, and a solid phase potential and a liquid phase potential are selected as a costate variable.

The values of the observed quantity at the two endpoints of the calculation region are definite and known, but the costate variable is not certain.

If the starting point of the calculation region is an endpoint proximal to a current collector, the solid phase current of the starting point at the present time is equal to an external current at the present time, and the liquid-phase current is 0; the solid phase current of the corresponding end point at the present time is 0, and the liquid phase current is the external current at the present time. If the starting point of the calculation region is an endpoint distal to a current collector and the corresponding end point is proximal to the current collector, the conclusions are reversed.

At step S1000, inserting (N−1) nodes between two endpoints of the calculation region, and determining a target value of the observed quantity of each node according to a preset interpolation method.

Specifically, several nodes may be inserted at equal or unequal intervals between two endpoints of the calculation region.

Unevenly spaced insertion methods can utilize Gaussian integral points or Chebyshev points to partition grids.

Chebyshev points are defined as follows:

$${z}_{j} = cos \frac{j π}{M} ,$$

0<=j<=M. The Chebyshev point when M=8 is shown in FIG. 5. If M is equal to N, the z₀˜z_{N} points can be obtained according to the above formula, wherein z₀ and z_{N} are the two endpoints of the calculation region, and z₁˜z_{N-1} are the inserted (N−1) nodes. Utilizing Chebyshev points for grid partitioning can improve calculation precision.

An interpolation function can be constructed according to a preset interpolation method, calculating a target value of the observed quantity of each node according to the interpolation function. The domain of the interpolation function is the calculation region, and the values of the interpolation function at two endpoints of the calculation region are respectively equal to the values of the observed quantities at the corresponding endpoints of the calculation region. The preset interpolation method uses existing techniques such as one of a linear interpolation method, a Lagrange interpolation method and a Newton interpolation method.

At step S2000, constructing N calculation units.

The (N−1) nodes divide the calculation region into N sub-regions, each sub-region serving as a calculation unit. That is, the starting point of the first calculation unit is the starting point of the calculation region, and the end point is the first inserted node; the starting point of the i-th calculation unit is the (i−1)-th inserted node, the end point is the i-th inserted node, and i=2, . . . , N−1; the starting point of the N-th calculation unit is the (N−1)-th inserted node, and the end point is the end point of the calculation region.

At step S3000, respectively performing a target shooting on the N calculation units to obtain a target shooting value of the observed quantity of an end point of each calculation unit.

The target value of the observed quantity of the (N−1)-th node was set in step S1000. The target value of the observed quantity of the i-th node is the target value of the observed quantity of the i-th calculation unit at the end point, and is also the value of the observed quantity of the (i+1)-th calculation unit at the start point, where i=1, . . . , N−1. Each calculation unit performs target shooting by adopting a conventional shooting method, initiating shooting from the starting point of the calculation unit to the end point of the calculation unit, and the target for shooting is the target value of the observed quantity of the node corresponding to the end point of the calculation unit.

In one embodiment, a one-time target shooting of one calculation unit refers to a process of gradually obtaining a targeting value of an observed quantity of an endpoint of the computing unit from an observed value of a starting point of the calculation unit according to a plurality of control equations (i.e., PDE, partial differential equation) in the electrochemical model after a certain value is taken for a costate variable of the starting point of the calculation unit. The calculation unit can obtain the target shooting value of the observed quantity of the end point corresponding to the value of the costate variable of the starting point every time the target shooting is performed. However, since the value of the costate variable at the starting point of the calculation unit is a trial solution, one-time target shooting cannot ensure that the obtained target shooting value of the observed quantity of the end point of the calculation unit converges on the target value of the observed quantity of the node corresponding to the end point.

At step S4000, determining whether a distance between the target shooting value of the observed quantity of the end point of each calculation unit and the target value of the observed quantity of the node corresponding to the end point of said calculation unit is within a preset range;

At step S5000, if the distance of any calculation unit is not within the preset range, adjusting the target value of the observed quantity of the node corresponding to the end point of said calculation unit according to the target shooting value of the observed quantity of the end point of said calculation unit, and jumping back to step S3000.

At step S6000, if all the distances of the calculation units are within the preset range, obtaining a continuous target shooting curve from the starting point to the end point of the calculation region, and obtaining electric field physical quantities of each spatial point in the calculation region at the present time according to said target shooting curve.

The electric field physical quantity includes solid phase current, liquid phase current, solid phase potential, and liquid phase potential.

If the target shooting value of the observed quantity of the end point of the i-th calculation unit is equal to the target value of the observed quantity of the node corresponding to the end point, namely the target shooting value of the observed quantity of the end point of the i-th calculation unit is equal to the value of the observed quantity of the starting point of the (i+1)-th calculation unit, the curve is continuous at the end point of the i-th calculation unit (namely, the i-th node). If the curve is continuous at all nodes, the curve formed by the N sub-curves is continuous.

If the derivative value of the observed quantity of the end point of the i-th calculation unit on the i-th sub-curve is equal to the derivative value of the observed quantity of the starting point of the (i+1)-th calculation unit on the (i+1)-th sub-curve, the curve is smooth at the end point of the i-th calculation unit (i.e., the i-th node). If the curve is smooth at all nodes, the curve made up of the N sub-curves is smooth. The i-th sub-curve is obtained by target shooting of the i-th calculation unit.

Step S4000 is equivalent to checking the continuity of the curve at all nodes. If there is any discontinuity, the target value of the observed quantity of the node is adjusted, a sub-curve is obtained through re-shooting, and the curve formed by the new sub-curve is checked as to whether it is continuous.

In one embodiment, step S4000 includes, in addition to determining whether the distance between the target shooting value of the observed quantity of the end point of each calculation unit and the target value of the observed quantity of the node corresponding to the end point of said calculation unit is within the preset range, determining whether the distance between the derivative value of the observed quantity of the end point of each calculation unit on the corresponding sub-curve and the derivative value of the observed quantity of the starting point of the next calculation unit on the corresponding sub-curve is within the preset range, that is, checking the continuity and smoothness of the curve at each node.

Step S5000 is correspondingly adjusted to, if there is at least one node where the curve is not continuous or smooth, adjust the target value of the observed quantity of the node, and the process jumps back to step S3000 to obtain a sub-curve by re-shooting and checking whether the curve formed by the new sub-curve is continuous and smooth.

Thus, a continuous and smooth target shooting curve from the start point to the end point of the calculation region can be obtained.

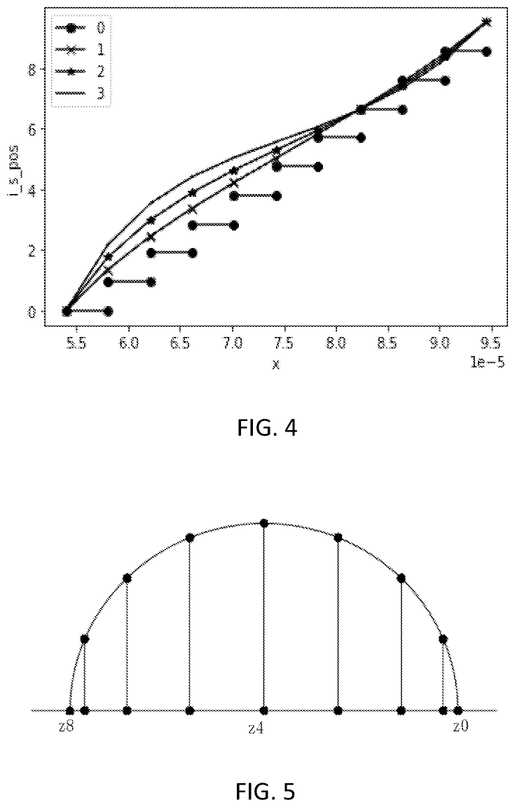

For example, as shown in FIG. 4, the horizontal axis represents a spatial position, the vertical axis represents a solid phase current (i.e., an observed quantity), the graph is an example of adjusting a target value of the observed quantity, 0, 1, 2, and 3 represent convergence processes, and a curve corresponding to 3 represents a convergence solution.

A plurality of nodes are inserted between two endpoints of the calculation region, the nodes divide the calculation region into a plurality of sub-regions, and each sub-region is a calculation unit. Parallel targeting is performed on all the calculation units. In the first parallel targeting (nodes are marked by large round points), the target shooting of each unit is not converged, and the No. 0 curve formed by the targeting curves of all the calculation units is discontinuous. Iteration is carried out, and the target value of the observed quantity of the node is updated; the second parallel targeting is performed according to the target value of the observed quantity of the new node, wherein the No. 1 curve may appear continuous due to image display limitations, but the No. 1 curve is discontinuous or unsmooth at some nodes, so the target value of the observed quantity of the node continues to be adjusted, and the third parallel targeting is performed. The iterative process continues until a continuous and smooth curve (namely, the No. 3 curve) from the starting point to the end point of the calculation region is obtained through the fourth parallel targeting, the No. 3 curve is a convergence solution, and the observed value and the costate value of each node on the curve are the required convergence solutions.

In one embodiment, a calculation region is divided into N calculation units with small tracking lengths by inserting (N−1) nodes, a target value of the observed quantity of each node is set roughly, then a targeting method is applied to the N calculation units in parallel, and then the target value of the observed quantity of each node is adjusted iteratively, so that the target shooting value of the observed quantity of the end point of each calculation unit converges to the target value of the observed quantity of the node corresponding to the end point, thereby obtaining a continuous and smooth target shooting curve from a starting point to an end point of the calculation region, and obtaining an electric field physical quantity of each spatial point in the calculation region according to the targeting curve. The method not only avoids the phenomena that the conventional target shooting method has high dependency on the initial trial solution and data overflow or non-convergence easily occurs in the target shooting process, but also improves operational speed and processing efficiency compared with a multiple serial shooting method.

The method for solving the electric field physical quantity of the negative electrode region is consistent with that of the positive electrode region. One region can be solved first, and then the other region can be solved according to the same method, so that solving of the electric field physical quantity for the entire spatial domain is completed.

In one embodiment, step S1000 includes:
if the observed quantity is the solid phase current, obtaining the target value of the observed quantity at the i-th node by a formula of:

$$\frac{{i}_{external}}{L} \times ( L - {x}_{i} ) ,$$

wherein iₑₓₜₑᵣₙₐₗ is an external current, L is a thickness of an electrode, and xᵢ is a distance from the i-th node to a current collector.

The target value of the observed quantity of the node is obtained according to a linear interpolation method.

In one embodiment, the performing a target shooting on one calculation unit in step S3000 includes:
At step S3100, starting from the starting point of the calculation unit, calculating the observed quantity and the costate variable of the next spatial point at the present time according to the observed quantity and the costate variable of the present spatial point at the present time, updating the present spatial point with the next spatial point, and repeating the above steps until the observed quantity and the costate variable of the end point of the calculation unit at the present time are obtained.

In some embodiments, the calculating the observed quantity and the costate variable of the next spatial point at the present time according to the observed quantity and the costate variable of the present spatial point at the present time in step S3100 includes:
At step S3110, according to the solid phase potential and the liquid phase potential of the present spatial point at the present time, obtaining an overpotential of the present spatial point at the present time by the formula of:

η(x, t)=ϕₛ(x, t)−ϕₑ(x, t)−ocv(x, t);

wherein η is the overpotential, ϕₛ is the solid phase potential, ϕₑ is the liquid phase potential, and ocv is an electrode steady state open circuit voltage related to a lithium ion concentration on surfaces of solid phase particles. The distribution of ocv on the x-axis can be obtained in advance before the electric field is decoupled.

At step S3120, according to the overpotential of the present spatial point at the present time, obtaining an exchange current density of the present spatial point at the present time by the formula of:

$${j}_{n} ( x , t ) = \frac{1}{F} {j}_{0} ( x , t ) [ exp ( \frac{{α}^{+} F}{RT} η ( x , t ) ) - exp ( - \frac{{α}^{-} F}{RT} η ( x , t ) ) ] ;$$

wherein α⁺ and α⁻ are transfer coefficients, F is a Faraday constant, R is a molar gas constant, T is an absolute temperature of the battery, and j₀ is the exchanging current density for an electrode reaction in an equilibrium state.

At step S3130, according to the exchange current density of the present spatial point at the present time, calculating the observed quantity of the next spatial point at the present time by using a difference method or a Runge-Kutta method.

The next spatial point is equal to the present spatial point plus the preset pace (step length). The exchange current density not only reflects the change of lithium ion current per unit area, but also reflects the change of electron current. The observed quantity is the solid phase current or the liquid phase current. Therefore, according to the observed quantity and the exchange current density of the present spatial point, the observed quantity of the next spatial point is obtained.

At step S3140, obtaining the partial derivative of the solid-phase potential of the current spatial point at the present time according to the observed quantity of the current spatial point at the present time, and calculating the solid phase potential at the next spatial point according to the partial derivative of the solid phase potential of the current spatial point at the present time by using the difference method or the Runge-Kutta method.

If the observed quantity is the solid phase current, the partial derivative of the solid-phase potential at the present spatial point at the present time can be obtained according to the formula of

$$\frac{\partial {ϕ}_{s}}{\partial x} : \frac{\partial {ϕ}_{s}}{\partial x} ( x , t ) = - \frac{{i}_{s} ( x , t )}{k} ,$$

wherein iₛ is the solid phase current and k is a solid phase conductivity.

If the observed quantity is the liquid phase current, according to iₛ(x, t)+iₑ(x, t)=iₑₓₜₑᵣₙₐₗ(t), wherein iₑₓₜₑᵣₙₐₗ is the external current, the solid phase current at the present spatial point at the present time is obtained first, and then the partial derivative of the solid phase potential at the present spatial point at the present time is obtained according to the above formula.

Using the difference method or the Runge-Kutta method, the solid phase potential of the next spatial point can be obtained according to the solid phase potential of the present spatial point at the present time and the partial derivative of the solid phase potential.

At step S3150, obtaining the partial derivative of the liquid phase potential of the present spatial point at the present time, and calculating the liquid phase potential of the next spatial point by the difference method or Runge-Kutta method according to the partial derivative of the liquid phase potential of the present spatial point at the present time.

Specifically, if the observed quantity is the solid phase current, according to iₛ(x, t)+iₑ(x, t)=iₑₓₜₑᵣₙₐₗ(t), the liquid phase current at the present spatial point at the present time can be obtained.

The partial derivative of the liquid phase potential at the present spatial point is obtained according to the formula of

$$\frac{\partial {ϕ}_{e}}{\partial x} :$$

$$\frac{\partial {ϕ}_{e}}{\partial x} ( x , t ) = - \frac{{i}_{e} ( x , t )}{σ * {ε}^{brug}} + \frac{2 RT}{F} ( 1 - {t}_{c} ) \frac{\partial ln {c}_{e}}{\partial x} ( x , t ) ,$$

wherein iₑ is the liquid phase current, t_{c} is the point mobility, cₑ is a liquid phase lithium-ion concentration, σ is a liquid phase conductivity, ε is a liquid phase volume fraction, and brug is a porous media coefficient.

According to the liquid phase potential of the present spatial point and the partial derivative of the liquid phase potential, the liquid phase potential of the next spatial point is calculated.

In one embodiment, the adjusting the target value of the observed quantity of the node corresponding to the end point of said calculation unit according to the target shooting value of the observed quantity of the end point of said calculation unit in step S5000 includes:
At step S5100, constructing a target function according to the distance between the target shooting value of the observed quantity of the end point of all the calculation units and the target value of the observed quantity of the corresponding node;
At step S5200, obtaining an iterative update formula of the target value of the observed quantity of the node that enables the value of the target function to approach 0 by adopting an iterative method; and
At step S5300, updating the target value of the observed quantity of the node according to the iterative update formula.

For example, the 2-norm of the difference between the target shooting value of the observed quantity of the end point of all the calculation units and the target value of the observed quantity of the corresponding node is taken as the target function, i.e., the target function F(X) is constructed according to a formula of:

$$F ( X ) = {\sum }_{i = 1}^{N} {( {end}_{i} - {start}_{i + 1} )}^{2} ;$$

wherein, X is a vector consisting of the observed values of the starting points of all the calculation units and the costate values, wherein the observed value of the starting point of the first calculation unit is definite, and others are uncertain. endᵢ is the target shooting value of the observed quantity of the end point of the i-th calculation unit obtained through target shooting according to the observed value of the starting point of the i-th calculation unit and the target value of the costate value, and is a function of the observed value of the starting point of the i-th calculation unit and the costate value. startᵢ₊₁ is the observed value at the starting point of the (i+1)-th calculation unit, and is also the target value of the observed quantity of the node corresponding to the end point of the i-th calculation unit.

Using the target function, it can be determined whether the resulting curve is sufficiently continuous and smooth. Specifically, when the target function is smaller than the tolerance, the resulting curve is considered to be sufficiently continuous and smooth.

With respect to obtaining an approximate solution for F(X)=0 and obtaining the target value of the observed quantity of all nodes satisfying the requirement, the problem is equivalent to solving a nonlinear least squares problem. An iterative updating formula of the target value of the observed quantity of each node is obtained by adopting an iterative method. If the target shooting process can be represented analytically, iterative updating of the target value of the observed quantity of the node can be obtained by adopting a steepest descent method, a Newton iterative method, a conjugate gradient method, or other methods. If the target shooting process cannot be analytically represented or the expressions are too complex, iterative updating of the target value of the observed quantity of the node can be obtained by using a quasi-Newton method.

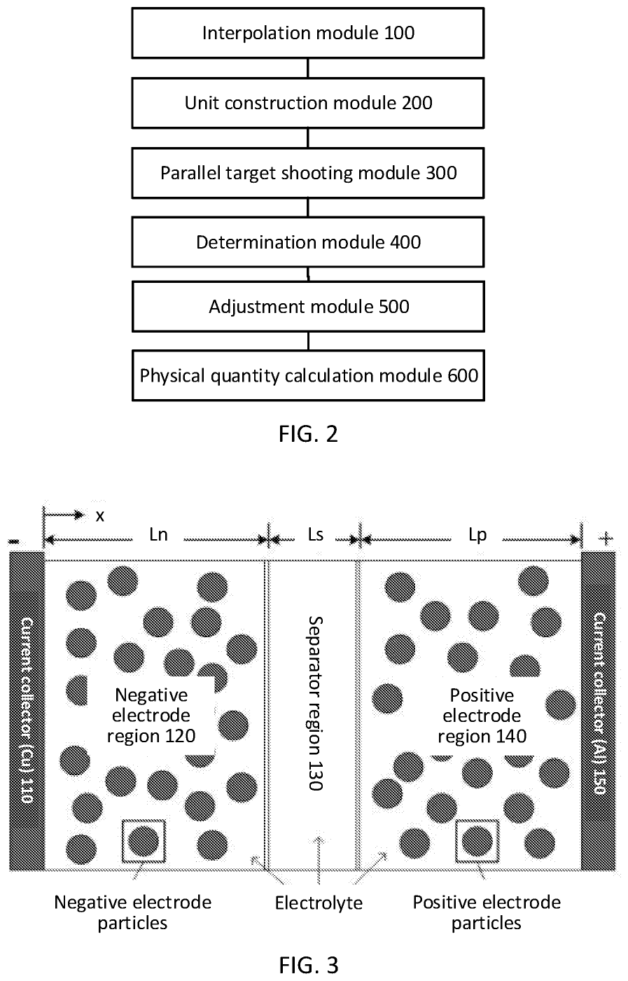

Referring to FIG. 2, a system for decoupling electric field of electrochemical model based on a parallel targeting method is schematically shown according to one embodiment of the invention. A negative electrode region or a positive electrode region of the electrochemical model of a lithium ion battery is selected as a calculation region, a solid phase current or a liquid phase current is selected as an observed quantity, and a solid phase potential and a liquid phase potential are selected as a costate variable.

The system comprises an interpolation module 100, a unit construction module 200, a parallel target shooting module 300, a determination module 400, an adjustment module 500, and a physical quantity calculation module 600.

The interpolation module 100 is configured to insert (N−1) nodes between two endpoints of the calculation region, and determine a target value of the observed quantity of said nodes according to a preset interpolation method.

The unit construction module 200 is configured to construct N calculation units, wherein the (N−1) nodes divide the calculation region into N sub-regions, each sub-region serving as a calculation unit.

The parallel target shooting module 300 is configured to respectively perform a target shooting on the N calculation units to obtain a target shooting value of the observed quantity of an end point of each calculation unit.

The determination module 400 is configured to determine whether a distance between the target shooting value of the observed quantity of the end point of each calculation unit and the target value of the observed quantity of the node corresponding to the end point of said calculation unit is within a preset range.

The adjustment module 500 is configured to, if the distance of any calculation unit is not within the preset range, adjust the target value of the observed quantity of the node corresponding to the end point of said calculation unit according to the target shooting value of the observed quantity of the end point of said calculation unit, perform the target shooting on said N calculation units again, determine whether the distance between the target shooting value of the observed quantity of the end point of each calculation unit and the target value of the observed quantity of the corresponding node is within the preset range, and repeat the above steps until said distances of all the calculation units are within the preset range.

The physical quantity calculation module 600 is configured to obtain, according to the observed quantity of the starting point at the present time and the deterministic solution of the costate variable, the electric field physical quantity of each spatial point of the calculation region at the present time.

In some embodiments, the interpolation module 100 is also configured to:
according to the preset interpolation method, construct an interpolation function, wherein values of the interpolation function at the two endpoints of the calculation region are respectively equal to values of the observed quantity of the endpoints corresponding to the calculation region, and wherein the preset interpolation method is one of a linear interpolation method, a Lagrange interpolation method and a Newton interpolation method; and calculate the target value of the observed quantity of each node according to the interpolation function.

In some embodiments, the interpolation module 100 is also configured to:
if the observed quantity is the solid-phase current, obtain the target value of the observed quantity at the i-th node by a formula of:

$$\frac{{i}_{external}}{L} \times ( L - {x}_{i} ) ,$$

wherein iₑₓₜₑᵣₙₐₗ is an external current, L is a thickness of an electrode, and xᵢ is a distance from the i-th node to a current collector.

In some embodiments, the adjustment module 500 is also configured to construct a target function according to the distance between the target shooting value of the observed quantity of the end point of all the calculation units and the target value of the observed quantity of the corresponding node; obtain an iterative update formula of the target value of the observed quantity of the node that enables the value of the target function to approach 0 by adopting an iterative method; and adjust the target value of the observed quantity of the node according to the iterative update formula.

It should be noted that the embodiment of the system for decoupling electric field of electrochemical model based on the parallel targeting method provided by the invention and the embodiment of the method for decoupling electric field of electrochemical model based on the parallel targeting method provided above are all according to the same inventive concept, and can obtain the same technical effects. Therefore, other specific content of the embodiment of the system for decoupling electric field of electrochemical model based on the parallel targeting method can refer to the description of the content of the embodiment of the above-mentioned method for decoupling electric field of electrochemical model based on the parallel targeting method.

In one embodiment, a non-transitory tangible computer-readable storage medium stores a computer program, and when the computer program is executed by a processor, the method for decoupling electric field of electrochemical model based on the parallel targeting method as described in the foregoing embodiments can be realized. That is, when part or all of the technical solutions contributed by the embodiments of the invention to the prior art are embodied in the form of computer software products, the foregoing computer software products are stored in a computer-readable storage medium. The computer-readable storage medium may be any portable computer program code entity or device. For example, the computer-readable storage medium may be a USB flash drive, a removable disk, a magnetic disk, an optical disk, a computer memory, a read-only memory, a random access memory, and the like.

The foregoing description of the exemplary embodiments of the invention has been presented only for the purposes of illustration and description and is not intended to be exhaustive or to limit the invention to the precise forms disclosed. Many modifications and variations are possible in light of the above teaching. The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the invention pertains without departing from its spirit and scope. Accordingly, the scope of the invention is defined by the appended claims rather than the foregoing description and the exemplary embodiments described therein.

What is claimed is:

1. A method for decoupling electric field of electrochemical model based on a parallel targeting method, comprising:
selecting a negative electrode region or a positive electrode region of the electrochemical model of a lithium ion battery as a calculation region;
selecting a solid phase current or a liquid phase current as an observed quantity, and a solid phase potential and a liquid phase potential as a costate variable;
inserting (N−1) nodes between two endpoints of the calculation region, and determining a target value of the observed quantity of each node according to a preset interpolation method;
constructing N calculation units, wherein the (N−1) nodes divide the calculation region into N sub-regions, each sub-region serving as a calculation unit;
respectively performing a target shooting on the N calculation units to obtain a target shooting value of the observed quantity of an end point of each calculation unit;
determining whether a distance between the target shooting value of the observed quantity of the end point of each calculation unit and the target value of the observed quantity of the node corresponding to the end point of said calculation unit is within a preset range; and
if the distance of any calculation unit is not within the preset range, adjusting the target value of the observed quantity of the node corresponding to the end point of said calculation unit according to the target shooting value of the observed quantity of the end point of said calculation unit, performing the target shooting on said N calculation units again, determining whether the distance between the target shooting value of the observed quantity of the end point of each calculation unit and the target value of the observed quantity of the corresponding node is within the preset range, and repeating above steps until said distances of all the calculation units are within the preset range.

2. The method of claim 1, wherein said determining the target value of the observed quantity of each node according to the preset interpolation method comprises:
according to the preset interpolation method, constructing an interpolation function, wherein values of the interpolation function at the two endpoints of the calculation region are respectively equal to values of the observed quantity of the endpoints corresponding to the calculation region, and wherein the preset interpolation method is one of a linear interpolation method, a Lagrange interpolation method and a Newton interpolation method; and
calculating the target value of the observed quantity of each node according to the interpolation function.

3. The method of claim 1, comprising:
if the observed quantity is the solid phase current, obtaining the target value of the observed quantity at the i-th node by a formula of:
$$\frac{{i}_{external}}{L} \times ( L - {x}_{i} ) ,$$
wherein iₑₓₜₑᵣₙₐₗ is an external current, L is a thickness of an electrode, and xᵢ is a distance from the i-th node to a current collector.

4. The method of claim 1, wherein said adjusting the target value of the observed quantity of the node corresponding to the end point of said calculation unit according to the target shooting value of the observed quantity of the end point of said calculation unit comprises:
constructing a target function according to the distance between the target shooting value of the observed quantity of the end point of all the calculation units and the target value of the observed quantity of the corresponding node;
obtaining an iterative update formula of the target value of the observed quantity of the node that enables the value of the target function to approach 0 by adopting an iterative method; and
adjusting the target value of the observed quantity of the node according to the iterative update formula.

5. The method of claim 4, wherein the iterative method is one of a Newton iterative method, a steepest descent method, a conjugate gradient method and a quasi-Newton iterative method.

6. The method of claim 1, wherein the (N−1) nodes are Chebyshev points.

7. A system for decoupling electric field of electrochemical model based on a parallel targeting method, wherein a negative electrode region or a positive electrode region of the electrochemical model of a lithium ion battery is selected as a calculation region, a solid phase current or a liquid phase current is selected as an observed quantity, and a solid phase potential and a liquid phase potential are selected as a costate variable, the system comprising:
an interpolation module, configured to insert (N−1) nodes between two endpoints of the calculation region, and determine a target value of the observed quantity of each node according to a preset interpolation method;
a unit construction module, configured to construct N calculation units, wherein the (N−1) nodes divide the calculation region into N sub-regions, each sub-region serving as a calculation unit;
a parallel target shooting module, configured to respectively perform a target shooting on the N calculation units to obtain a target shooting value of the observed quantity of an end point of each calculation unit;
a determination module, configured to determine whether a distance between the target shooting value of the observed quantity of the end point of each calculation unit and the target value of the observed quantity of the node corresponding to the end point of said calculation unit is within a preset range; and
an adjustment module, configured to, if the distance of any calculation unit is not within the preset range, adjust the target value of the observed quantity of the node corresponding to the end point of said calculation unit according to the target shooting value of the observed quantity of the end point of said calculation unit, perform the target shooting on said N calculation units again, determine whether the distance between the target shooting value of the observed quantity of the end point of each calculation unit and the target value of the observed quantity of the corresponding node is within the preset range, and repeat above steps until said distances of all the calculation units are within the preset range.

8. The system of claim 7, comprising:
wherein said interpolation module is further configured to, according to the preset interpolation method, construct an interpolation function, wherein values of the interpolation function at the two endpoints of the calculation region are respectively equal to values of the observed quantity of the endpoints corresponding to the calculation region, and wherein the preset interpolation method is one of a linear interpolation method, a Lagrange interpolation method and a Newton interpolation method; and calculate the target value of the observed quantity of each node according to the interpolation function.

9. The system of claim 7, comprising:
wherein said interpolation module is further configured to, if the observed quantity is the solid phase current, obtain the target value of the observed quantity at the i-th node by a formula of:
$$\frac{{i}_{external}}{L} \times ( L - {x}_{i} ) ,$$
wherein iₑₓₜₑᵣₙₐₗ is an external current, L is a thickness of an electrode, and xᵢ is a distance from the i-th node to a current collector.

10. A non-transitory tangible computer-readable storage medium, storing a computer program therein, wherein when the computer program is executed by a processor, the method for decoupling electric field of electrochemical model based on a parallel targeting method according to claim 1 is realized.
